(19) United States
(12) Patent Application Publication
(10) Pub. No.: US 2010/0244067 A1
(43) Pub. Date: Sep. 30, 2010

(54) PHOSPHOR PLATES FOR LEDS FROM STRUCTURED FILMS

(75) Inventors: Holger Winkler, Darmstadt (DE); Klaus Ambrosius, Dieburg (DE); Ralf Petry, Griesheim (DE)

Correspondence Address: MILLEN, WHITE, ZELANO & BRANIGAN, P.C., 2200 CLARENDON BLVD., SUITE 1400, ARLINGTON, VA, 22201, US

(73) Assignee: MERCK PATENT GESELLSCHAFT, Darmstadt (DE)

(21) Appl. No.: 12/514,937

(22) PCT Filed: Oct. 25, 2007
(86) PCT No.: PCT/EP2007/009278

§ 371 Date: May 14, 2009

(30) Foreign Application Priority Data
Nov. 17, 2006 (DE) 10 2006 054 330.0

(51) Int. Cl. H01L 33/44; C09K 11/77; B05D 5/12; B32B 5/16

(52) U.S. Cl. 257/98; 252/301.4 R; 252/301.4 F; 427/66; 428/403; 428/406; 257/E33.061

(57) ABSTRACT

The invention relates to a phosphor element which is based on natural and/or synthetic flake-form substrates, such as mica, corundum, silica, glass, ZrO₂ or TiO₂, and at least one phosphor, to the production thereof, and to the use thereof as LED conversion phosphor for white LEDs or so-called colour-on-demand applications.

The invention relates to a phosphor element which is based on natural and/or synthetic, highly stable, flake-form substrates, such as mica (aluminosilicate), corundum (Al₂O₃), silica (SiO₂), glass, ZrO₂ or TiO₂, and at least one phosphor, to the production thereof via structured films, and to the use thereof as LED conversion phosphor for white LEDs or so-called colour-on-demand applications.

White LEDs represent the future technology for generating light artificially. So-called phosphor converted pcLEDs or luminescence converted lucoLEDs will, according to the general opinion of light and energy experts, replace incandescent bulbs and halogen bulbs to a perceptible extent from 2010. From 2015, fluorescent tubes will be replaced.

However, this generally accepted road map will only occur if the technology of pcLEDs achieves important advances by the year 2010: Today, a white 1 W power pcLED has a wall-plug efficiency of 15%, i.e. 15% of the electrical energy coming from the socket is converted into visible light, the remainder is lost as heat. In contrast to the incandescent bulb, the principle of which was discovered more than 100 years ago by Edison and has not changed since, this represents a clear improvement: only 5% of the energy entering the incandescent bulb is converted into visible light, the remainder is lost as heat and heats up the environment. At present, the lumen efficiency of a commercially available white 1 W power pcLED corresponds to about 45 lm/W (lumens/watt), while the lumen efficiency of an incandescent bulb is less than 20 lm/W. The loss factors of the pcLED lie principally in the phosphor, which is required in white pcLEDs for emission of white light and in colour-on-demand LED applications for the generation of a certain colour point, and in the semiconductor chip of the LED itself and the structure of the LED (packaging).

The colour-on-demand concept is taken to mean the generation of light of a certain colour point by means of a pcLED using one or more phosphors. This concept is used, for example, to produce certain corporate designs, for example for illuminated company logos, trademarks, etc.

The phosphors currently used for white pcLEDs which contain a blue-emitting chip as primary emitter, are principally YAG:Ce³⁺ or derivatives thereof, or orthosilicate:Eu²⁺.

The phosphors are prepared by solid-state diffusion processes (“mixing and firing”) by mixing oxidic starting materials as powders, grinding the mixture and then calcining the mixture in an oven at temperatures up to 1700° C. for up to several days in an optionally reducing atmosphere. This gives phosphor powders which have inhomogeneities in relation to the morphology, the particle-size distribution and the distribution of the luminescent activator ions in the volume of the matrix. Furthermore, the morphology, particle-size distributions and further properties of these phosphors prepared by the traditional process can only be adjusted poorly and are difficult to reproduce. These particles therefore have a number of disadvantages, such as, in particular, inhomogeneous coating of the LED chips with these phosphors having non-optimal and inhomogeneous morphology and particle-size distribution, which result in high loss processes due to scattering. Further losses arise in the production of these LEDs through the fact that the phosphor coating of the LED chips is not only inhomogeneous, but is also not reproducible from LED to LED. This results in variations of the colour points of the emitted light from the pcLEDS even within a batch. This makes a complex sorting process of the LEDs (so-called binning) necessary. The phosphor particles are applied to the LED by a complex process. To this end, the phosphor particles are dispersed in a binder, usually silicones or epoxides, and one or more drops of this dispersion are applied to the chip. While the binder hardens, non-uniform sedimentation behaviour occurs in the phosphor particles due to different morphology and size, resulting in inhomogeneous coating within a LED and from LED to LED. For this reason, complex classification processes have to be carried out (so-called binning), where the LEDs are sorted according to whether they meet or do not meet optical target parameters, such as the distribution of optical parameters within the light cone with respect to distribution of the colour temperature, chromaticity (x,y values within the CIE chromaticity diagram), and the optical performance, in particular the light flux expressed in lumens and the lumen efficiency (lm/W). This sorting results in a reduction in the time yield of LED units per machine day since >>30% of the LEDs are usually rejected. This situation results in the high unit costs, in particular of power LEDs (i.e. LEDs having a power requirement of greater than 0.5 W), which can be at prices of several US $ per unit, even in the region of purchase quantities of more than 10,000 units.

The object of the present invention is therefore to provide phosphors, preferably conversion phosphors for white LEDs or for colour-on-demand applications, which do not have one or more of the above-mentioned disadvantages. The phosphor element here should be in flake form and have a diameter of greater than 20 μm.

Surprisingly, the present object can be achieved by producing the phosphor element by wet-chemical methods, even in the form of thin flakes, by means of a structured substrate (for example in a polyethylene terephthalate film).

The process according to the invention for the production of these phosphors and the use of these phosphors in LEDs result in a reduction in the production costs of white LEDs and/or LEDs for colour-on-demand applications since the phosphor-induced inhomogeneity and low batch-to-batch reproducibility of the light properties of LEDs are eliminated and the application of the phosphor to the LED chip is simplified and accelerated. Furthermore, the light yield of white LEDs and/or colour-on-demand applications can be increased with the aid of the process according to the invention. Overall, the costs of the LED light become lower because:
the costs per LED become lower (investment costs for the customers)
more light is obtained from an LED (more favourable lumen/EUR ratio)
overall, the total cost of ownership, which describes the light costs as a function of the investment costs, the maintenance costs and the operating and replacement costs, becomes more favourable.

The present invention thus relates to a phosphor element consisting of a phosphor-coated substrate comprising mica, glass, ZrO₂, TiO₂, SiO₂ or Al₂O₃ flakes or mixtures thereof.

A phosphor element is particularly preferably obtainable by
preparation of a phosphor precursor suspension by mixing at least two starting materials and at least one dopant by wet-chemical methods,
preparation of an aqueous suspension of mica, glass, ZrO₂, TiO₂, SiO₂ or Al₂O₃ flakes or mixtures thereof,
application of the aqueous suspension to a structured support medium with formation of a substrate film,
solidification of the substrate film by drying and separation of the dried substrate film from the support medium,
addition of the phosphor precursor suspension and subsequent addition of a precipitation reagent with formation of a phosphor element precursor,
subsequent thermal treatment of the phosphor element precursor.

This object is furthermore achieved in accordance with the invention by a phosphor element obtainable by
preparation of a phosphor precursor suspension by mixing at least two starting materials and at least one dopant by wet-chemical methods,
preparation of an aqueous suspension of mica, glass, ZrO₂, TiO₂, SiO₂ or Al₂O₃ flakes or mixtures thereof,
combination of the two suspensions prepared above to give the substrate
application of the substrate to a structured support medium with formation of a substrate film,
solidification of the substrate film by drying and separation of the dried substrate film from the support medium with formation of a phosphor element precursor,
subsequent thermal treatment of the phosphor element precursor to give the phosphor element obtained.

This object is furthermore achieved in accordance with the invention by a phosphor element obtainable by
preparation of a phosphor precursor suspension by mixing at least two starting materials and at least one dopant by wet-chemical methods,
application of the phosphor precursor suspension to a structured support medium with formation of a substrate film,
solidification of the substrate film by drying and separation of the dried substrate film from the support medium with formation of a phosphor element precursor,
subsequent thermal treatment of the phosphor element precursor to give the phosphor element obtained.

In the last-mentioned embodiment, the phosphor element according to the invention thus consists merely of one or more phosphor materials, i.e. it does not comprise a substrate of mica, glass, ZrO₂, TiO₂, SiO₂ or Al₂O₃ flakes or mixtures thereof.

The phosphor element or the phosphor flakes having diameters of greater than 20 μm can be produced by coating a natural or synthetically prepared, highly stable support or a substrate of mica, SiO₂, Al₂O₃, ZrO₂, glass or TiO₂ flakes which has a very large aspect ratio, an atomically smooth surface and an adjustable thickness with a phosphor layer by a precipitation reaction in aqueous suspension or dispersion. Besides mica, ZrO₂, SiO₂, Al₂O₃, glass or TiO₂ or mixtures thereof, the flakes may also be built up from the phosphor material itself. If the flake itself merely serves as support for the phosphor coating, the latter must consist of a material which is transparent to the primary radiation of the LED or absorbs the primary radiation and transfers this energy to the phosphor layer.

The use of the flake-form phosphors makes the LED light cone more homogeneous (colour point and brightness) and increases the reproducibility from LED to LED, reducing or even eliminating binning.

Furthermore, the scattering properties of this phosphor layer are more favourable than those of irregular phosphor powders, since the light emitted by the LED chip is scattered back less by the surface of the flake than by the surface of non-uniform powders dispersed in resin. More light can thus be absorbed and converted by the phosphor. As a result, the light efficiency of white LEDs is increased.

However, the phosphor elements according to the invention can also be installed directly on top of a finished blue or UV LED or at a separation from the chip (so-called “remote phosphor content”). It is thus possible to influence the light temperature and hue of the light by simple exchange of the phosphor flake. This can be carried out most simply by exchanging the chemically identical phosphor substance in the form of flakes of different thickness.

In particular, the material selected for the phosphor elements according to the invention can be the following compounds, where, in the following notation, the host lattice is shown to the left of the colon and one or more doping elements are shown to the right of the colon. If chemical elements are separated from one another by commas and bracketed, they can be used optionally. Depending on the desired luminescence property of the phosphor elements, one or more of the compounds provided for selection can be used:

BaAl₂O₄:Eu²⁺, BaAl₂S₄:Eu²⁺, BaB₈O₁₋₃:Eu²⁺, BaF₂, BaFBr:Eu²⁺, BaFCl:Eu²⁺, BaFCl:Eu²⁺, Pb²⁺, BaGa₂S₄:Ce³⁺, BaGa₂S₄:Eu²⁺, Ba₂Li₂Si₂ O₇:Eu²⁺, Ba₂Li₂Si₂O₇:Sn²⁺, Ba₂Li₂Si₂O₇:Sn²⁺, Mn²⁺, BaMgAl_{,0}O₁₇:Ce³⁺, BaMgAl₁₀O₁₇:Eu²⁺, BaMgAl₁₀O₁₇:Eu²⁺, Mn²⁺, Ba₂Mg₃F₁₀:Eu²⁺, BaMg₃F₈:Eu²⁺,Mn²⁺, Ba₂MgSi₂O₇:Eu²⁺, BaMg₂Si₂O₇:Eu²⁺, Ba₅(PO₄)₃Cl:Eu²⁺, Ba₆(PO₄)₃Cl:U, Ba₃(PO₄)₂:Eu²⁺, BaS:Au,K, BaSO₄:Ce³⁺, BaSO₄:Eu²⁺, Ba₂SiO₂:Ce³⁺,Li⁺,Mn²⁺, Ba₅SiO₄Cl₆:Eu²⁺, BaSi₂O₅:Eu²⁺, Ba₂SiO₄:Eu²⁺, BaSi₂O₅:Pb²⁺, BaₓSri₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈ Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺,Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O,₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₅O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO4)₃Cl:Eu²⁺, CaBr₂:Eu²⁺ in SiO₂, CaCl₂:Eu²⁺ in SiO₂, CaCl₂:Eu²⁺,Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO.Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₆(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺,Mn²⁺, Ca₅(PO₄)₃F:Mn²⁺, Caₛ(PO₄)₃F:Sb³⁺, Caₛ(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺,Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄O₂:Eu²⁺, Ca₃SiO₄Cl₂:Pb²⁺, CaSiO₃:Eu²⁺, CaSiO₃:Mn²⁺,Pb, CaSiO₃:Pb²⁺, CaSiO₃:Pb²⁺,Mn²⁺, CaSiO₃:Ti⁴⁺, CaSr₂(PO₄)₂:Bi³⁺, β-(Ca,SO₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺, Cr, CdS:In, CdS:In, CdS:In, Te, CdS:Te, CdWO₄, CsF, CsI, CsI:Na⁺, CsI:Tl, (ErCl₃)_{0.25}(BaCl₂)_{0.75}, GaN:Zn, Gd₃Ga₆O₁₂:Cr³⁺, Gd₃Ga₅O₁₂:Cr, Ce, GdNba₄:Bi³⁺, Gd₂O₂S:Eu³⁺, Gd₂O₂Pr³*, Gd₂O₂S:Pr, Ce, F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺, Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺, Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₆:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:Tl, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYE₄:Er³⁺, Yb³⁺, NaYO₂:Eu³⁺, P46(70%)+P47 (30%), SrAl₁₂O₁₉:Ce³⁺,Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺,Mn²⁺, SrB₈O₁₃:Sm²⁺, SrₓBa_{y}a_{z}Al₂O_{4-z/2}: Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺, Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺,Mn²⁺(Al), SrS:Ce³⁺, SrS:Eu²⁺, SrS:Mn²⁺, SrS:Cu⁺, Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃:Pr³⁺, Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺, Cr³⁺, YAl₃B₄O₁₂:Th⁴⁺, Ce³⁺, Mn²⁺, YAlO₃:Ce³⁺, Y₃Al₅O₁₂:Ce³⁺, (Y,Gd,Lu,Tb)₃(Al, Ga)₅O₁₂:(Ce,Pr,Sm), Y₃Al₅O₁₂:Cr³⁺, YAlO₃:Eu³⁺, Y₃Al₅O₁₂:Eu³⁺, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺, Yb³⁺, YF₃:Mn²⁺, YF₃:Mn²⁺, Th⁴⁺, YF₃:Tm³⁺, Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBrEu³⁺, Y₂O₃:Ce, Y₂O₃:Er³⁺, Y₂O₃:Eu³⁺(YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺,Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS-CdS:Ag⁺,Cl, ZnS-CdS:Cu,Br, ZnS—CdS:Cu,I, ZnS:C⁻, ZnS:Eu²⁺, ZnS:Cu, ZnS:Cu⁺,Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺,Cl, ZnWO₄.

The phosphor element preferably consists of at least one of the following phosphor materials:

(Y, Gd, Lu, Sc, Sm, Tb)₃ (Al, Ga)₅O₁₂:Ce (with or without Pr), (Ca, Sr, Ba)₂SiO₄:Eu, YSiO₂N:Ce, Y₂Si₃O₃N₄:Ce, Gd₂Si₃O₃N₄:Ce, (Y,Gd,Tb,Lu)₃Al₅₋ₓSiₓO₁₂₋ₓNₓ:Ce, BaMgAl₁₀O₁₇:Eu, SrAl₂O₄:Eu, Sr₄Al₁₄O₂₅:Eu, (Ca,Sr,Ba)Si₂N₂O₂:Eu, SrSiAl₂O₃N₂:Eu, (Ca,Sr,Ba)₂Si₅N₈:Eu, CaAlSiN₃:Eu, zinc/alkaline earth metal orthosilicates, copper/alkaline earth metal ortho-silicates, iron/alkaline earth metal orthosilicates, molybdates, tungstates, vanadates, group III nitrides, oxides, in each case individually or mixtures thereof with one or more activator ions, such as Ce, Eu, Mn, Cr and/or Bi.

The phosphor element can be produced on a large industrial scale as flakes in thicknesses from 10 μm to 5 mm, preferably between 20 μm and 100 μm. The flake size in the two other dimensions (length×width) in the case of application directly to the chip is from 100 μm×100 μm to 8 mm×8 mm, preferably 120 μm×120 μm to 3 mm×3 mm.

If the phosphor flakes are installed on top of a finished LED and/or at a separation from the LED chip, which may include the remote phosphor arrangement, the emitted light cone will be picked up in its entirety by the flake.

The flake-form phosphor element generally has an aspect ratio (ratio of the diameter to the particle thickness) of 2:1 to 400:1 and in particular 1.5:1 to 100:1.

The substrate employed in the phosphor element preferably consists of SiO₂ and/or Al₂O₃.

The side surfaces of the phosphor element according to the invention may be metallised with a light or noble metal, preferably aluminium or silver. The metallisation has the effect that light does not exit laterally from the phosphor element according to the invention due to wave conduction. Light exiting laterally can reduce the light flux to be coupled out of the LED. The metallisation of the phosphor element can be carried out in a process step after production of the phosphor element. To this end, the side surfaces are wetted, for example with a solution of silver nitrate and glucose, and subsequently exposed to an ammonia atmosphere at elevated temperature. During this operation, a silver coating, for example, forms on the side surfaces.

Alternatively, electroless metallisation processes are suitable, see, for example, Hollemann-Wiberg, Lehrbuch der Anorganischen Chemie [Text-book of Inorganic Chemistry], Walter de Gruyter Verlag, or Ullmanns Enzyklopädie der chemischen Technologie [Ullmann's Encyclopaedia of Chemical Technology].

Furthermore, the surface of the phosphor element according to the invention facing the LED chip can be provided with a coating which has a reflection-reducing action in relation to the primary radiation emitted by the LED chip. This likewise results in a reduction in back-scattering of the primary radiation, enhancing coupling of the latter into the phosphor element according to the invention.

Suitable for this purpose are, for example, refractive index-adapted coatings, which must have a following thickness d: d=[wavelength of the primary radiation from the LED chip/(4* refractive index of the phosphor ceramic)], see, for example, Gerthsen, Physik [Physics], Springer Verlag, 18th Edition, 1995. This coating may also consist of photonic crystals, which also includes structuring of the surface of the flake-form phosphor element in order to achieve certain functionalities.

In a further preferred embodiment, the flake-form phosphor element has a structured (for example pyramidal) surface on the side opposite an LED chip (see FIG. 5). This enables the largest possible amount of light to be coupled out of the phosphor element. Otherwise, light which hits the flake-form phosphor element/environment interface at a certain angle, the critical angle, experiences total reflection, resulting in undesired conduction of the light within the phosphor element.

The structured surface on the phosphor element is produced by subsequent coating with a suitable material which has already been structured, or in a subsequent step by (photo)lithographic processes, etching processes or by writing processes using energy or material beams or the action of mechanical forces.

A further possibility consists in structuring the surface of the phosphor according to the invention itself by the use of the above-mentioned processes.

In a further preferred embodiment, the phosphor element according to the invention has, on the side opposite an LED chip, a rough surface (see FIG. 5) which carries nanoparticles of SiO₂, TiO₂, Al₂O₃, ZnO₂, ZrO₂ and/or Y₂O₃ or combinations of these materials or of particles comprising the phosphor composition. A rough surface here has a roughness of up to a few 100 nm. The coated surface has the advantage that total reflection can be reduced or prevented and the light can be coupled out of the phosphor element according to the invention better.

In a further preferred embodiment, the phosphor element according to the invention has a refractive index-adapted layer on the surface facing away from the chip, which simplifies the coupling-out of the primary radiation and/or the radiation emitted by the phosphor element.

In a further preferred embodiment, the phosphor element has a polished surface in accordance with DIN EN ISO 4287 (roughness profile test; polished surfaces have roughness class N3-N1) on the side facing an LED chip. This has the advantage that the surface area is reduced, causing less light to be scattered back.

In addition, this polished surface may also be provided with a coating which is transparent to the primary radiation, but reflects the secondary radiation. The secondary radiation can then only be emitted upwards. It is also preferred for the side of the phosphor element facing an LED chip to have a surface provided with antireflection properties for the radiation emitted by the LED.

The starting materials for the production of the phosphor element consist of the base material (for example salt solutions of yttrium, aluminium, gadolinium, etc.) and at least one dopant (for example cerium). Suitable starting materials are inorganic and/or organic substances, such as nitrates, halides, carbonates, hydrogencarbonates, phosphates, carboxylates, alcoholates, acetates, oxalates, sulfates, organometallic compounds, hydroxides and/or oxides of the metals, semimetals, transition metals and/or rare earths, which are dissolved and/or suspended in inorganic and/or organic liquids. Preference is given to the use of mixed nitrate solutions, chloride or hydroxide solutions which contain the corresponding elements in the requisite stoichiometric ratio.

This object is furthermore achieved in accordance with the invention by a process for the production of a phosphor element having the following process steps:
a) preparation of a phosphor precursor suspension by mixing at least two starting materials and at least one dopant by wet-chemical methods,
b) preparation of an aqueous suspension of mica, glass, ZrO₂, TiO₂, SiO₂ or Al₂O₃ flakes or mixtures thereof,
c) application of the aqueous suspension prepared under step b to a structured support medium with formation of a substrate film,
d) solidification of the substrate film by drying and separation of the dried substrate film from the support medium,
e) addition of the phosphor precursor suspension prepared under step a and subsequent addition of a precipitation reagent with formation of a phosphor element precursor,
f) subsequent thermal treatment of the phosphor element precursor.

The use of structured support media, preferably comprising organic materials (for example polyethylene terephthalate films) or also ceramic materials (for example corundum), enables flake-form phosphor elements having a diameter of between 20 μm and up to 5 mm to be produced.

The structured support medium consists of cells (preferably square), which are filled with the substances from which the flakes are produced. The size of the flakes is determined by the dimensions of the cells (length×width×depth) (see FIGS. 1 to 3). After the cells have been filled, the contents of the cells are solidified at elevated temperatures. The heating here can be carried out up to a temperature (preferably from 180 to 800° C.) at which the structured support material or the cells, if these consist of polymers, are burned away, enabling the flakes to be isolated or removed. Alternatively, the cells can also be removed by passing the flexible support medium in the form of a continuous belt around a reverse roll, with the solidified flakes detaching from the support medium.

The flakes here preferably consist of an inorganic substrate or binder material, such as mica, glass, ZrO₂, TiO₂, SiO₂ or Al₂O₃ flakes or mixtures thereof, which are coated with phosphor particles (such as, for example, YAG:Ce or orthosilicates). Preference is given here to the use of silica or corundum flakes.

The synthetic flakes are produced by conventional processes via a belt process from the corresponding alkali metal salts (for example for silica from a potassium or sodium water-glass solution). The production process is described in detail in EP 763573, EP 608388 and DE 19618564.

The flakes are then initially introduced as an aqueous suspension having a defined solids content of mica, glass, ZrO₂, TiO₂, SiO₂ or Al₂O₃ and then coated with phosphor precursors by the process known to the person skilled in the art via a structured support medium described above. To this end, salts of the desired components of the phosphor precursor (for example YAG:Ce) are precipitated on the surface of the substrate flakes. Under precisely defined conditions (such as, for example, the pH, the temperature and the presence of additives), the pre-formed phosphor precursor precipitates out in the suspension, and the particles formed are deposited on the substrate as a layer. After a number of purification steps, the phosphor-coated substrate is calcined at temperatures between 700 and 1800° C., preferably between 900 and 1700° C., for a number of hours. During this operation, the phosphor precursor or the phosphor element precursor (preferably in the form of a phosphor hydroxide) is converted into the actual flake-form phosphor element (preferably in oxide form).

It is preferred to carry out the calcination at least partly under reducing conditions (for example with carbon monoxide, forming gas, pure hydrogen or at least a vacuum or oxygen deficiency atmosphere).

This is preferably a one- or multistep subsequent thermal treatment in the above-mentioned temperature range. This subsequent thermal treatment particularly preferably consists of a two-step process, where the first process can be shock heating, which is carried out at temperature T₁, and the second process can be a conditioning process at temperature T₂. The shock heating can be initiated, for example, by introducing the sample to be heated into the oven which has already been heated to T₁. T₁ here is 700 to 1800° C., preferably 900 to 1600° C., and for T₂ values of between 1000 and 1800° C., preferably 1200 to 1700° C., apply. The first process runs over a period of 1-2 h. The material can then be cooled to room temperature and ground finely and gently with low input of energy. The conditioning process at T₂ takes place over a period of, for example, 2 to 8 hours. The conditioning process can be carried out in a reducing atmosphere.

This two-step subsequent thermal treatment has the advantage that the partially crystalline or amorphous, finely divided, surface-reactive phosphor powder is subjected to partial sintering in the first step at temperature T₁, and the formation of perfect crystal quality and the requisite oxidation state of the phosphor activator is retained or achieved in a subsequent thermal step at T₂.

The present invention furthermore relates to a process for the production of a phosphor precursor having the following process steps:
a) preparation of a phosphor precursor suspension by mixing at least two starting materials and at least one dopant by wet-chemical methods,
b) preparation of an aqueous suspension of mica, glass, ZrO₂, TiO₂, SiO₂ or Al₂O₃ flakes or mixtures thereof,
c) combination of the suspensions prepared under steps a and b to give the substrate
d) application of the substrate to a structured support medium and formation of a substrate film,
e) solidification of the substrate film by drying and separation of the dried substrate film from the support medium with formation of a phosphor element precursor,
f) subsequent thermal treatment of the phosphor element precursor to give the phosphor element obtained.

In the second process variant according to the invention, the inorganic substrate comprising mica, glass, ZrO₂, TiO₂, SiO₂ or Al₂O₃ flakes or mixtures thereof is mixed with the phosphor precursor suspension, and a substrate film is produced therefrom on top of a structured support medium by means of the belt process. No coating of the inorganic substrate with phosphor particles thus takes place (as in the first process according to the invention), but instead the phosphor particles are embedded in the inorganic substrate (see FIG. 4).

A further process variant relates to a process for the production of phosphor elements having the following process variants:
a) preparation of a phosphor precursor suspension by mixing at least two starting materials and at least one dopant by wet-chemical methods,
b) application of the phosphor precursor suspension to a structured support medium with formation of a substrate film,
c) solidification of the substrate film by drying and separation of the dried substrate film from the support medium with formation of a phosphor element precursor,
d) subsequent thermal treatment of the phosphor element precursor to give the phosphor element obtained.

In this third process variant, an inorganic substrate comprising mica, glass, ZrO₂, TiO₂, SiO₂ or Al₂O₃ flakes or mixtures thereof is not employed for the production of the phosphor element according to the invention. The phosphor elements produced in this way are particularly preferred if the highest possible phosphor concentration as conversion material is necessary.

Wet-chemical production generally has the advantage that the resultant materials according to the invention have greater uniformity with respect to the stoichiometric composition, the particle size and the morphology of the particles from which the phosphor element according to the invention is produced. The wet-chemical production of the phosphor element is preferably carried out by the precipitation and/or sol-gel process. The advantage of the phosphor elements according to the invention is that they are suitable for storage and can be installed directly on the LED chip without a resin dispersion if the former has a flip-chip design. Conventional LED chips with connecting wires on the surface cannot be equipped directly with the phosphor flakes according to the invention. Here, the optical coupling of the phosphor element to the chip must take place using, for example, a transparent resin.

The present invention furthermore relates to an illumination unit having at least one primary light source whose emission maximum is in the range 240 to 510 nm, where the primary radiation is partially or fully converted into longer-wavelength radiation by the phosphor element according to the invention. This illumination unit is preferably white-emitting or emits light having a certain colour point (colour-on-demand principle).

In a preferred embodiment of the illumination unit according to the invention, the light source is a luminescent indium aluminium gallium nitride, in particular of the formula InᵢGaᵢAlₖN, where 0≦i, 0≦j, 0≦k, and i+j+k=1.

Possible forms of light sources of this type are known to the person skilled in the art. They can be light-emitting LED chips having various structures.

In a further preferred embodiment of the illumination unit according to the invention, the light source is a luminescent arrangement based on ZnO, TCO (transparent conducting oxide), ZnSe or SiC or an arrangement based on an organic light-emitting layer.

The flake-form phosphor element can either be arranged directly on the primary light source or alternatively arranged at a distance therefrom, depending on the application (the latter arrangement also includes “remote phosphor technology”). The advantages of “remote phosphor technology” are known to the person skilled in the art and are revealed, for example, by the following publication: Japanese Journ. of Appl. Phys. Vol. 44, No. 21 (2005). L649-L651.

In a further embodiment, it is preferred for the optical coupling of the illumination unit between the phosphor element and the primary light source to be achieved by a light-conducting arrangement. This enables the primary light source to be installed at a central location and to be optically coupled to the phosphor by means of light-conducting devices, such as, for example, light-conducting fibres. In this way, lights matched to the illumination wishes and merely consisting of one or different phosphor elements, which may be arranged to form a light screen, and a light conductor, which is coupled to the primary light source, can be achieved. In this way, it is possible to position a strong primary light source at a location which is favourable for the electrical installation and to install lights comprising phosphor elements which are coupled to the light conductors at any desired locations without further electrical cabling, but instead only by laying light conductors.

It may furthermore be preferred for the illumination unit to consist of one or more phosphor elements which have identical or different structures.

The present invention furthermore relates to the use of the phosphor element according to the invention for the conversion of blue or near-UV emission into visible white radiation. Furthermore, the use of the phosphor element according to the invention for conversion of the primary radiation into a certain colour point in accordance with the colour-on-demand concept is preferred.

In a preferred embodiment, the phosphor element can be employed as conversion phosphor for visible primary radiation for the generation of white light. In this case, it is particularly advantageous for high luminous power if the phosphor element absorbs a certain proportion of the visible primary radiation (in the case of invisible primary radiation, this should be absorbed in its entirety) and the remainder of the primary radiation is transmitted in the direction of the surface opposite the primary light source. It is furthermore advantageous for high luminous power if the phosphor element is as transparent as possible to the radiation emitted by it with respect to coupling-out via the surface opposite the material emitting the primary radiation.

In a further preferred embodiment, the phosphor element can be employed as conversion phosphor for UV primary radiation for the generation of white light. In this case, it is advantageous for high luminous power if the phosphor element absorbs all the primary radiation and if the phosphor element is as transparent as possible to the radiation emitted by it.

The following examples are intended to illustrate the present invention. However, they should in no way be regarded as limiting. All compounds or components which can be used in the compositions are either known and commercially available or can be synthesised by known methods. The temperatures indicated in the examples are always given in ° C. It furthermore goes without saying that, both in the description and also in the examples, the added amounts of the components in the compositions always add up to a total of 100%. Percentage data given should always be regarded in the given connection. However, they usually always relate to the weight of the part-amount or total amount indicated.

### EXAMPLES

### Example 1

### Production of Silica Flakes Having Dimensions of 2 mm×2 mm×100 μm

A commercially available sodium water-glass solution is firstly diluted with deionised water in the ratio 1:2.5, and 1% by weight of additive (Disperse Ayd W22) is added. After the solution has been homogenised by stirring, it is applied to a polyethylene terephthalate film (PET film) which has a periodic structure with the preferred dimension, consisting of square cells having a base area of 2 mm×2 mm and a depth of 100 μm (see FIGS. 1 and 2). The applied film is dried at 100° C. and subsequently detached on passing over a reverse roll (see FIG. 3). The crude silica flakes obtained are conditioned in an aqueous solution comprising dilute hydrochloric acid at pH=5.

### Example 2

### Coating of the Flakes from Ex. 1 With YAG:Ce Phosphor, Starting From Nitrate Precursors

(Precipitation reaction at pH 7-9)

2.94 Y³⁺+0.06 Ce³⁺+5 Al³⁺24 OH⁻→(Y_{0.98}Ce_{0.02})(OH)_{3 +}⇓5Al(OH)₃⇓

Thermal conversion at 1000° C.:

3(Y_{0.98}Ce_{0.02})(OH)₃₊5Al(OH)₃→(Y_{0.98}Ce_{0.02})₃Al₅O₁₂++12H₂O⇑

Silica flakes from Example 1 are introduced into a coating vessel as aqueous suspension having a solids content of less than 50 g/l.

The suspension is subsequently heated to 75° C. and stirred gently at less than 100 rpm.

An aqueous solution comprising the precursor of the actual phosphor is then prepared as follows:

157.10 g of Al(NO₃)₃×9 H₂O are dissolved in 600 ml of deionised H₂O with stirring on a magnetic stirrer plate. When the salt has completely dissolved, the mixture is stirred for a further 5 min. Y(NO₃)₃×6 H₂O (94.331 g) is then added and likewise dissolved, and the mixture is stirred for a further 5 min. 2.183 g of Ce(NO₃)₃×6 H₂O complete the composition of the nitrate solution.

This solution is metered by means of a glass inlet tube into the stirred suspension which comprises the silica substrate.

Sodium hydroxide solution is simultaneously metered into the said suspension by means of a second inlet tube. The pH of the suspension is thus kept constant at 8.0 during the precipitation reaction.

The pre-formed YAG:Ce phosphor then precipitates in the suspension at the pH described, and the phosphor nanoparticles formed deposit on the silica or Al₂O₃ substrate, i.e. the flakes are coated with the phosphor particles.

The coating process is complete after about 30 h. The suspension is then stirred for a further 2 h, and the material is filtered off with suction as described, rinsed and calcined at 1000° C. for about 6 h. During the calcination, the phosphor precursor (phosphor hydroxide) is converted into the actual phosphor in the oxide form. A second calcination is then carried out under reducing conditions (CO or forming gas) at temperatures up to 1200° C.

### Example 3

### Preparation of YAG:Ce Phosphor on Silica Flakes, Starting From Chloride Precursors

(Precipitation reaction at pH 7-9)

2.94Y³⁺+0.06Ce³⁺+5 Al³⁺24 OH⁻→3(Y_{0.98}Ce_{0.02})(OH)₃⇓+5Al(OH)₃⇓

Thermal conversion at 1000° C.:

3(Y_{0.98}Ce_{0.02})(OH)₃+5Al(OH)₃→(Y_{0.98}Ce_{0.02})₃Al₅O₁₂++12H₂O⇑

Silica flakes or Al₂O₃ flakes (preparation see DE 4134600 and EP 763 573) are introduced into a coating vessel as an aqueous suspension having a solids content of 50 g/l.

The suspension is subsequently heated to 75° C. and stirred vigorously at 1000 rpm.

An aqueous solution which comprises the precursor of the actual phosphor is then prepared as follows:

101.42 g of AlCl₃×6H₂O are dissolved in 600 ml of deionised H₂O with stirring on a magnetic stirrer plate. When the salt has completely dissolved, the mixture is stirred for a further 5 min. YCl₃×6H₂O (74.95 g) is then added and likewise dissolved, and the mixture is stirred for a further 5 min. 1.787 g of CeCl₃×6 H₂O complete the composition of the chloride solution.

This solution is metered by means of a glass inlet tube into the stirred suspension which comprises the silica and/or Al₂O₃ substrate. Sodium hydroxide solution is simultaneously metered into the said suspension by means of a second inlet tube. The pH of the suspension is thus kept constant at 7.5 during the precipitation reaction.

The pre-formed YAG:Ce phosphor then precipitates in the suspension at the pH described, and the phosphor nanoparticles formed deposit on the silica substrate, i.e. the flakes are coated with the phosphor particles.

The coating process is complete after about 30 h. The suspension is then stirred for a further 2 h, and the material is filtered off with suction as described, rinsed and calcined at 1000° C. for about 6 h. During the calcination, the phosphor precursor (phosphor hydroxide) is converted into the actual phosphor (the oxide form). The calcination here is carried out under reducing conditions (for example CO atmosphere).

### Example 4

### Incorporation of YAG:Ce Phosphor Particles Into Silica Flakes

A commercially available sodium water-glass solution is firstly diluted with deionised water in the ratio 1:2.5, and 1% by weight of additive (Disperse AYT-W22, Poro-Additive GmbH) is added. After homogenisation of the mixture, 30% by weight of YAG phosphor (preparation analogous to Example 2 or 3), based on the SiO₂ content, are added with stirring. The dispersion is subsequently mixed vigorously for 1 h using a suitable stirrer (propeller stirrer, Ultra-Turrax or the like). After the solution has been homogenised by stirring, it is applied to a support medium consisting of a polyethylene terephthalate film which has a rectangular structure having the preferred dimension. The applied film is dried at 100° C. and subsequently detached. The crude silica flakes obtained are conditioned in an aqueous solution comprising dilute hydrochloric acid at pH=5 and subsequently calcined at 800° C.

### Example 5

### Production of YAG:Ce Phosphor Flakes

(Precipitation reaction at pH 7-9)

2.94Y³⁺+0.06Ce³⁺+5 Al³⁺24 OH⁻→3(Y_{0.98}Ce_{0.02})(OH)₃⇓+5Al(OH)₃⇓

Thermal conversion at 1000° C.:

3(Y_{0.98}Ce_{0.02})(OH)₃+5Al(OH)₃→(Y_{0.98}Ce_{0.02})₃Al₅O₁₂++12H₂O⇑

101.42 g of AlCl₃×6 H₂O are dissolved in 600 ml of deionised H₂O with stirring on a magnetic stirrer plate. When the salt has completely dissolved, the mixture is stirred for a further 5 min. YCl₃×6H₂O (74.95 g) is then added and likewise dissolved, and the mixture is stirred for a further 5 min. 1.787 g of CeCl₃×6 H₂O complete the composition of the chloride solution.

This solution is metered into the cells of a structured support medium or belt by means of a glass inlet tube.

Sodium hydroxide solution is simultaneously metered into the said suspension by means of a second inlet tube. The pH of the suspension is thus kept approximately neutral during the precipitation reaction.

The pre-formed YAG:Ce phosphor then precipitates in the suspension at the pH described. The suspension is then dried and solidified. The solidified plates are separated from the structured support medium and subsequently treated thermally.

The subsequent thermal treatment is carried out in a two-step process: the material is calcined at 1000° C. in air for 4 h, then the material is calcined at 1700° C. in a reducing atmosphere (forming gas) over a period of 6 h.

### BRIEF DESCRIPTION OF THE FIGURES

It is intended to explain the invention in greater detail below with reference to a number of embodiments.

FIG. 1 shows a side view of the structured film consisting of cells having a certain depth. The cells represent the template for the mica, glass, ZrO₂, TiO₂, SiO₂ or Al₂O₃ flakes. (1=PET film, nominal breaking point for the mica, glass, ZrO₂, TiO₂, SiO₂ or Al₂O₃ flakes)

FIG. 2 shows a plan view of the film structure, which consists of rectangular cells arranged alongside one another.

FIG. 3: The cells are filled with the liquid or dissolved precursor substances for the flakes—grey—(for example sodium water-glass), the precursor substances are dried and heated—grey—. The heating here can be carried out up to a temperature at which the structured support medium (for example PET film) is burned away, enabling the flakes (shown in grey) to be isolated. The dimensions of the flakes correspond to those of the cells. (1=structured PET film, nominal breaking point for the silica; 2=dried sodium water-glass)

FIG. 4 shows silica flakes, into which phosphor powders are embedded, consisting of YAG:Ce (1=phosphor particle, for example YAG:Ce; 2=silica flake matrix)

FIG. 5: The treatment in accordance with the invention of the flake-form phosphor element enables the production of pyramidal structures 2 on one surface of the flake (top). Nanoparticles of SiO₂, TiO₂, ZnO₂, ZrO₂, Al₂O₃, Y₂O₃, etc., or mixtures thereof or particles consisting of the phosphor composition can likewise be applied in accordance with the invention to one surface (rough side 3) of the flake-form phosphor element.

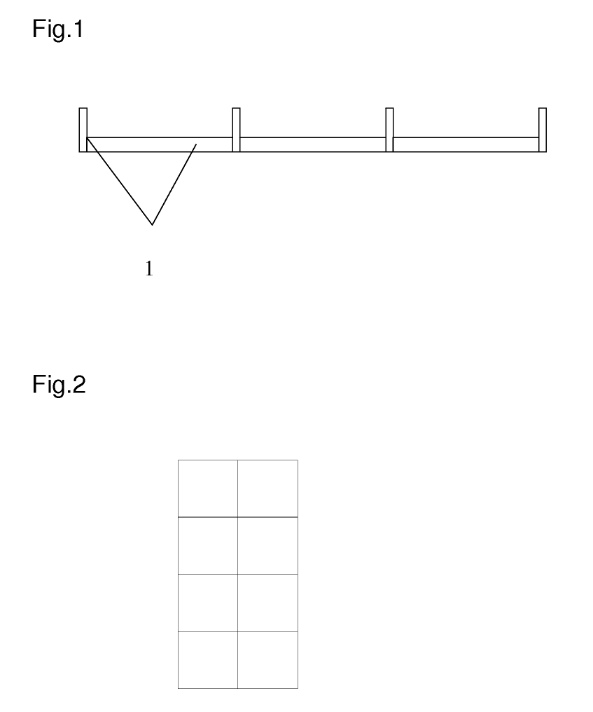

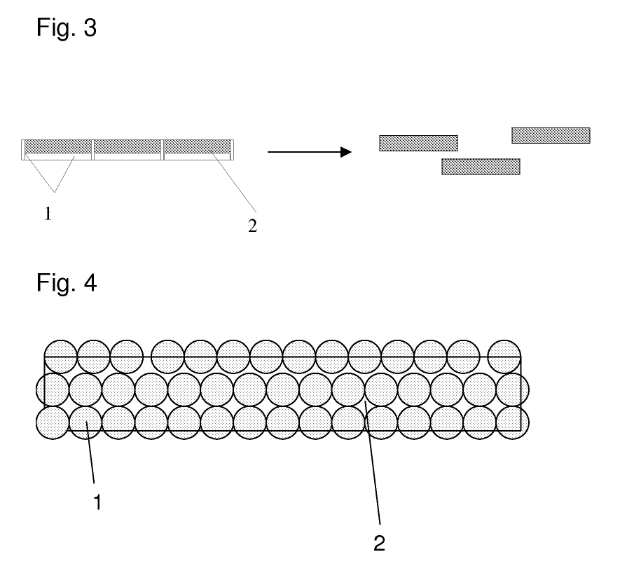

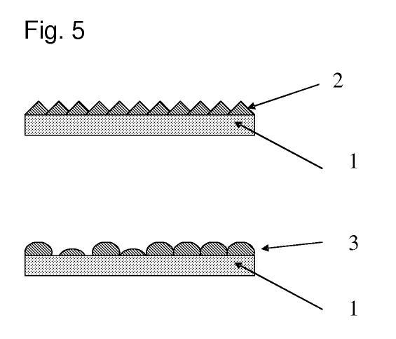

1. Phosphor element consisting of a phosphor-coated substrate comprising mica, glass, ZrO₂, TiO₂, SiO₂ or Al₂O₃ flakes or mixtures thereof.

2. Phosphor element obtainable by
preparation of a phosphor precursor suspension by mixing at least two starting materials and at least one dopant by wet-chemical methods,
preparation of an aqueous suspension of mica, glass, ZrO₂, TiO₂, SiO₂ or Al₂O₃ flakes or mixtures thereof,
application of the aqueous suspension to a structured support medium with formation of a substrate film,
solidification of the substrate film by drying and separation of the dried substrate film from the support medium,
addition of the phosphor precursor suspension and subsequent addition of a precipitation reagent with formation of a phosphor element precursor,
subsequent thermal treatment of the phosphor element precursor.

3. Phosphor element obtainable by
preparation of a phosphor precursor suspension by mixing at least two starting materials and at least one dopant by wet-chemical methods,
preparation of an aqueous suspension of mica, glass, ZrO₂, TiO₂, SiO₂ or Al₂O₃ flakes or mixtures thereof,
combination of the two suspensions prepared above to give the substrate
application of the substrate to a structured support medium with formation of a substrate film,
solidification of the substrate film by drying and separation of the dried substrate film from the support medium with formation of a phosphor element precursor,
a subsequent thermal treatment of the phosphor element precursor to give the phosphor element obtained.

4. Phosphor element obtainable by
preparation of a phosphor precursor suspension by mixing at least two starting materials and at least one dopant by wet-chemical methods,
application of the phosphor precursor suspension to a structured support medium with formation of a substrate film,
solidification of the substrate film by drying and separation of the dried substrate film from the support medium with formation of a phosphor element precursor,
subsequent thermal treatment of the phosphor element precursor to give the phosphor element obtained.

5. Phosphor element according to claim 1, characterised in that it is in flake form and has a thickness between 10 μm and 5 mm, preferably 20 μm to 100 μm.

6. Phosphor element according to claim 1, characterised in that the flake-form phosphor element has an aspect ratio of 2:1 to 400:1, preferably of 1.5:1 to 100:1.

7. Phosphor element according to claim 1, characterised in that the substrate consists of SiO₂ and/or Al₂O₃ flakes.

8. Phosphor element according to claim 1, characterised in that the side surfaces of the phosphor element have been metallised with a light or noble metal.

9. Phosphor element according to claim 1, characterised in that the side of the phosphor element opposite an LED chip has a structured surface.

10. Phosphor element according to claim 1, characterised in that the side of the phosphor element opposite an LED chip has a rough surface which carries nanoparticles of SiO₂, TiO₂, Al₂O₃, ZnO₂, ZrO₂ and/or Y₂O₃ or mixed oxides thereof or particles comprising the phosphor composition.

11. Phosphor element according to claim 1, characterised in that the side of the phosphor element facing an LED chip has a polished surface in accordance with DIN EN ISO 4287.

12. Phosphor element according to claim 1, characterised in that the side of the phosphor element facing an LED chip has a surface which is transparent in the forwards direction to the radiation emitted by the LED.

13. Phosphor element according to claim 1, characterised in that the side of the phosphor element facing an LED chip has a surface which is provided with antireflection properties for the radiation emitted by the LED.

14. Phosphor element according to claim 1, characterised in that the starting materials and the dopant are inorganic and/or organic substances, such as nitrates, carbonates, hydrogen-carbonates, phosphates, carboxylates, alcoholates, acetates, oxalates, halides, sulfates, organometallic compounds, hydroxides and/or oxides of the metals, semimetals, transition metals and/or rare earths which are dissolved and/or suspended in inorganic and/or organic liquids.

15. Phosphor element according to claim 1, characterised in that it consists of at least one of the following phosphor materials:
(Y, Gd, Lu, Sc, Sm, Tb)₃ (Al, Ga)₅O₁₂:Ce (with or without Pr), (Ca, Sr, Ba)₂SiO₄:Eu, YSiO₂N:Ce, Y₂Si₃O₃N₄:Ce, Gd₂Si₃O₃N₄:Ce, (Y,Gd,Tb,Lu)₃Al₅₋ₓSiₓO₁₂₋ₓNₓ:Ce, BaMgAl₁₀O₁₇:Eu, SrAl₂O₄:Eu, Sr₄Al₁₄O₂₅:Eu, (Ca,Sr,Ba)Si₂N₂O₂:Eu, SrSiAl₂O₃N₂:Eu, (Ca,Sr,Ba)₂Si₅N₈:Eu, CaAlSiN₃:Eu, zinc/alkaline earth metal orthosilicates, copper/alkaline earth metal orthosilicates, iron/alkaline earth metal orthosilicates, molybdates, tungstates, vanadates, group III nitrides, oxides, in each case individually or mixtures thereof with one or more activator ions, such as Ce, Eu, Mn, Cr and/or Bi.

16. Process for the production of a phosphor element having the following process steps:
a) preparation of a phosphor precursor suspension by mixing at least two starting materials and at least one dopant by wet-chemical methods,
b) preparation of an aqueous suspension of mica, glass, ZrO₂, TiO₂, SiO₂ or Al₂O₃ flakes or mixtures thereof,
c) application of the aqueous suspension prepared under step b to a structured support medium with formation of a substrate film,
d) solidification of the substrate film by drying and separation of the dried substrate film from the support medium,
e) addition of the phosphor precursor suspension prepared under step a and subsequent addition of a precipitation reagent with formation of a phosphor element precursor,
f) subsequent thermal treatment of the phosphor element precursor.

17. Process for the production of a phosphor element having the following process steps:
a) preparation of a phosphor precursor suspension by mixing at least two starting materials and at least one dopant by wet-chemical methods,
b) preparation of an aqueous suspension of mica, glass, ZrO₂, TiO₂, SiO₂ or Al₂O₃ flakes or mixtures thereof,
c) combination of the suspensions prepared under steps a and b to give the substrate
d) application of the substrate to a structured support medium and formation of a substrate film,
e) solidification of the substrate film by drying and separation of the dried substrate film from the support medium with formation of a phosphor element precursor,
f) subsequent thermal treatment of the phosphor element precursor to give the phosphor element obtained.

18. Process for the production of a phosphor element having the following process steps:
a) preparation of a phosphor precursor suspension by mixing at least two starting materials and at least one dopant by wet-chemical methods,
b) application of the phosphor precursor suspension to a structured support medium and formation of a substrate film,
c) solidification of the substrate film by drying and separation of the dried substrate film from the support medium with formation of a phosphor element precursor,
d) subsequent thermal treatment of the phosphor element precursor to give the phosphor element obtained.

19. Process according to claim 16, characterised in that the phosphor precursor is prepared in step a) by wet-chemical methods from organic and/or inorganic metal, semimetal, transition-metal and/or rare-earth salts by means of sol-gel processes and/or precipitation processes.

20. Process according to claim 16, characterised in that the structured support medium consists of an organic and/or ceramic material, preferably a polyethylene terephthalate film or corundum.

21. Process according to claim 16, characterised in that the subsequent thermal treatment is carried out in one or more steps at temperatures between 700 and 1800° C., preferably between 900 and 1700° C.

22. Process according to claim 16, characterised in that the surface of the phosphor element facing away from the LED chip is coated with nanoparticles comprising SiO₂, TiO₂, Al₂O₃, ZnO₂, ZrO₂ and/or Y₂O₃ or mixed oxides thereof or with nanoparticles comprising the phosphor composition.

23. Process according to claim 16, characterised in that a structured surface is produced on the side of the phosphor element facing away from the LED chip.

24. Illumination unit having at least one primary light source whose emission maximum is in the range 240 to 510 nm, where this radiation is converted partially or completely into longer-wavelength radiation by a phosphor element according to claim 1.

25. Illumination unit according to claim 24, characterised in that the light source is a luminescent indium aluminium gallium nitride, in particular of the formula InᵢGaⱼAlₖN where 0≦i, 0≦j, 0≦k, and i+j+k=1.

26. Illumination unit according to claim 24, characterised in that the light source is a luminescent material based on ZnO, TCO (transparent conducting oxide), ZnSe or SiC.

27. Illumination unit according to claim 24, characterised in that the light source is a material based on an organic light-emitting layer.

28. Illumination unit according to claim 24, characterised in that the phosphor element is arranged directly on the primary light source and/or remote therefrom.

29. Illumination unit according to claim 24, characterised in that the optical coupling between the phosphor element and the primary light source is achieved by a light-conducting arrangement.

30. Illumination unit according to claim 24, characterised in that the phosphor elements are an arrangement comprising one or more phosphor elements which have identical or different structures.

31. Use of the phosphor element according to claim 1, for conversion of blue or near-UV emission into visible white radiation.

32. Use of the phosphor element according to claim 1, for conversion of the primary radiation into a certain colour point in accordance with the colour-on-demand concept.
